(19) United States
(12) Patent Application Publication
(10) Pub. No.: US 2026/0348565 A1
(43) Pub. Date: Nov. 5, 2026

(54) LED LIGHTING DEVICE

(71) Applicant: Xiamen PVTECH Co., Ltd., Xiamen (CN)

(72) Inventors: FUXING LU, Xiamen (CN); RONGTU LIU, Xiamen (CN); HUIBAO LUO, Xiamen (CN); ZEHU DAI, Xiamen (CN); LIANGLIANG CAO, Xiamen (CN); CHUNMING LIU, Xiamen (CN); DEJIA LI, Xiamen (CN)

(21) Appl. No.: 19/734,879

(22) Filed: Jul. 8, 2026

Related U.S. Application Data
(63) Continuation-in-part of application No. 19/248,484, filed on Jun. 25, 2025, now Pat. No. 12,698,872.
Application No. 19/248,484 is a continuation-in-part of application No. 18/916,716, filed on Oct. 16, 2024, now Pat. No. 12,366,346.
Application No. 18/916,716 is a continuation-in-part of application No. 18/138,146, filed on Apr. 24, 2023, now Pat. No. 12,146,621.

(51) Int. Cl. F21V 19/00; F21Y 103/10; F21Y 113/13; F21Y 115/10

(52) U.S. Cl. CPC F21V 19/0025; F21Y 2103/10; F21Y 2113/13; F21Y 2115/10

(57) ABSTRACT

An LED lighting device includes a power supplier, a light cover, a circuit board and a plurality of light sources. The circuit board is disposed in the light cover. The circuit board includes a first electrical connection region, a second electrical connection region, and a circuit connection region. The first electrical connection region is connected to the positive output terminal of the power supplier and the second electrical connection region is connected to the negative output terminal of the power supplier. The circuit connection region includes a plurality of first curved portions and a plurality of second curved portions. The first curved portions and the second curved portions are alternately arranged to form a chain-link structure. The light sources are respectively disposed on the first electrical connection region, the second electrical connection region, and the circuit connection region.

### TECHNICAL FIELD

The disclosure relates to a lighting device, in particular to an LED lighting device.

### BACKGROUND

LED (light-emitting diode) light tubes have many advantages, such as high efficiency, low power consumption, long service life, etc., so LED light tubes have been comprehensively applied to various buildings. However, currently available LED light tubes still have many shortcomings to be overcome.

For example, a flexible printed circuit board (FPCB) used in a currently available LED light tube typically has a single ink protective layer formed on the surface thereof to cover conductive traces. However, such a single-layer ink protection scheme cannot provide targeted protection for different regions of the flexible printed circuit board, thereby resulting in limited protective performance.

In addition, the pattern and appearance of the single ink layer are relatively monotonous and lack distinctiveness and design flexibility, making it difficult to satisfy the aesthetic requirements of the product.

### SUMMARY

One embodiment of the disclosure provides an LED lighting device, which includes a power supplier, a light cover, a circuit board and a plurality of light sources. The circuit board is disposed in the light cover. The circuit board includes a first electrical connection region, a second electrical connection region, and a circuit connection region. The first electrical connection region is connected to the positive output terminal of the power supplier, and the second electrical connection region is connected to the negative output terminal of the power supplier. The circuit connection region includes a plurality of first curved portions and a plurality of second curved portions. Each of the first curved portions protrudes in a first direction, each of the second curved portions protrudes in a second direction opposite to the first direction. The first curved portions and the second curved portions are alternately arranged to form a chain-link structure. The light sources are respectively disposed on the first electrical connection region, the second electrical connection region, and the circuit connection region, such that the first electrical connection region, the second electrical connection region, and the circuit connection region are electrically connected to each other.

Further scope of applicability of the present application will become more apparent from the detailed description given hereinafter. However, it should be understood that the detailed description and specific examples, while indicating exemplary embodiments of the disclosure, are given by way of illustration only, since various changes and modifications within the spirit and scope of the disclosure will become apparent to those skilled in the art from this detailed description.

### BRIEF DESCRIPTION OF DRAWINGS

The disclosure will become more fully understood from the detailed description given herein below and the accompanying drawings which are given by way of illustration only, and thus are not limitative of the disclosure and wherein:

FIG. 1 is an exploded view of an LED lighting device in accordance with a first embodiment of the disclosure.

FIG. 2 is a perspective view of the LED lighting device in accordance with the first embodiment of the disclosure.

FIG. 3 is a first schematic view of a circuit board of the LED lighting device in accordance with the first embodiment of the disclosure.

FIG. 4 is a second schematic view of the circuit board of the LED lighting device in accordance with the first embodiment of the disclosure.

FIG. 5A is a third schematic view of the circuit board of the LED lighting device in accordance with the first embodiment of the disclosure.

FIG. 5B is a fourth schematic view of the circuit board of the LED lighting device in accordance with the first embodiment of the disclosure.

FIG. 6 is a first schematic view of a circuit board of the LED lighting device in accordance with a second embodiment of the disclosure.

FIG. 7 is a second schematic view of the circuit board of the LED lighting device in accordance with the second embodiment of the disclosure.

FIG. 8 is a third schematic view of the circuit board of the LED lighting device in accordance with the second embodiment of the disclosure.

FIG. 9 is a fourth schematic view of the circuit board of the LED lighting device in accordance with the second embodiment of the disclosure.

FIG. 10 is an enlargement view of a light cover of an LED lighting device in accordance with a third embodiment of the disclosure.

FIG. 11 is a sectional view of the LED lighting device in accordance with the third embodiment of the disclosure.

FIG. 12 is a sectional view of an LED lighting device in accordance with a fourth embodiment of the disclosure.

FIG. 13 is an exploded view of an LED lighting device in accordance with a fifth embodiment of the disclosure.

FIG. 14 is a first schematic view of a circuit board of the LED lighting device in accordance with the fifth embodiment of the disclosure (without the light sources).

FIG. 15 is a second schematic view of the circuit board of the LED lighting device in accordance with the fifth embodiment of the disclosure (without the light sources).

FIG. 16 is a partial enlargement view of the circuit board of the LED lighting device in accordance with the fifth embodiment of the disclosure (without the light sources).

FIG. 17 is a third schematic view of the circuit board of the LED lighting device in accordance with the fifth embodiment of the disclosure (with the light sources).

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing. It should be understood that, when it is described that an element is “coupled” or “connected” to another element, the element may be “directly coupled” or “directly connected” to the other element or “coupled” or “connected” to the other element through a third element. In contrast, it should be understood that, when it is described that an element is “directly coupled” or “directly connected” to another element, there are no intervening elements.

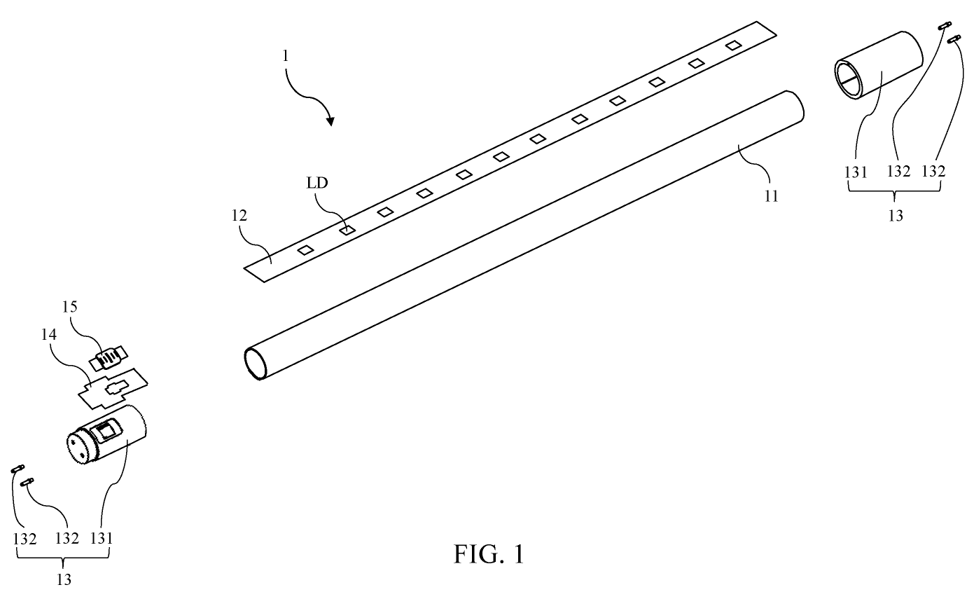

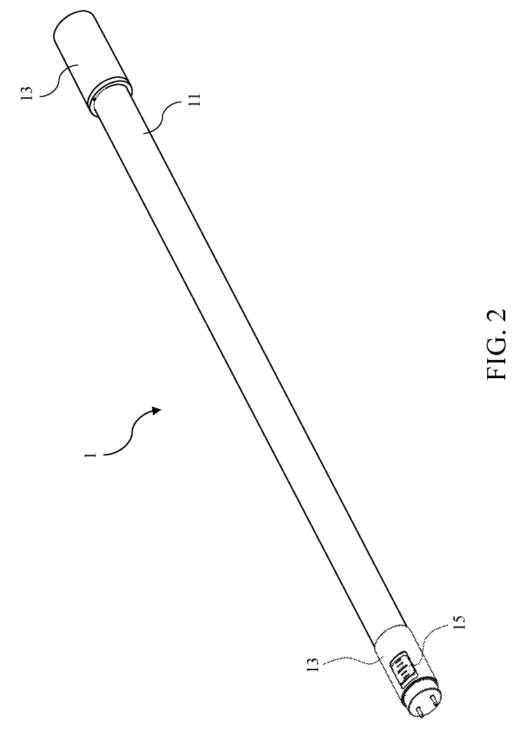

Please refer to FIG. 1 and FIG. 2. FIG. 1 is an exploded view of a light-emitting diode (LED) lighting device in accordance with a first embodiment of the disclosure. FIG. 2 is a perspective view of the LED lighting device in accordance with the first embodiment of the disclosure. As shown in FIG. 1 and FIG. 2, the LED lighting device 1 includes a light cover 11, a circuit board 12, two end caps 13, a power supplier 14, a color temperature switch 15 and a plurality of light sources LD. In this embodiment, the LED lighting device 1 is an LED light tube. In another embodiment, the LED lighting device 1 may be an LED panel light, LED ceiling light or other currently available lighting devices.

The circuit board 12 is disposed in the light cover 11. In this embodiment, the circuit board 12 is a flexible printed circuit board (FPCB). In another embodiment, the circuit board 12 is a printed circuit board. In this embodiment, the light cover 11 may be tubular. In another embodiment, the light cover 11 may be a flat circular box, a flat rectangular box, etc. In one embodiment, the light cover 11 may be made of a transparent material or a translucent material, such as plastics, glass, etc.

The two end caps 13 are disposed at the two ends of the light cover 11 and the power supplier 14 is disposed in one of the end caps 13 and electrically connected to the circuit board 12. Each of the end caps 13 includes a casing 131 and two metal pins 132 (e.g., copper, iron, aluminum, etc.). The metal pins 132 are disposed on the casing 131 and electrically connected to the power supplier 14 and the circuit board 12. In one embodiment, the power supplier 14 is an LED power supplier, which may include converters, rectifiers, filters and other necessary electronic components; the details of the power supplier 14 are known by those skilled in the art, so will not be described herein.

The light sources LD are disposed on the circuit board 12 and electrically connected to the circuit board 12. In this embodiment, the light sources LD are LEDs. In another embodiment, the light sources LD may be an LED light strip.

The color temperature switch 15 is disposed on one of the end caps 13 and connected to the power supplier 14. The user can operate the color temperature switch 15 to adjust the color temperature of the light sources LD. In another embodiment, the color temperature switch 15 may be replaced by a dimming switch, or the LED lighting device 1 may have both of the color temperature switch 15 and the dimming switch.

The embodiment just exemplifies the disclosure and is not intended to limit the scope of the disclosure; any equivalent modification and variation according to the spirit of the disclosure is to be also included within the scope of the following claims and their equivalents.

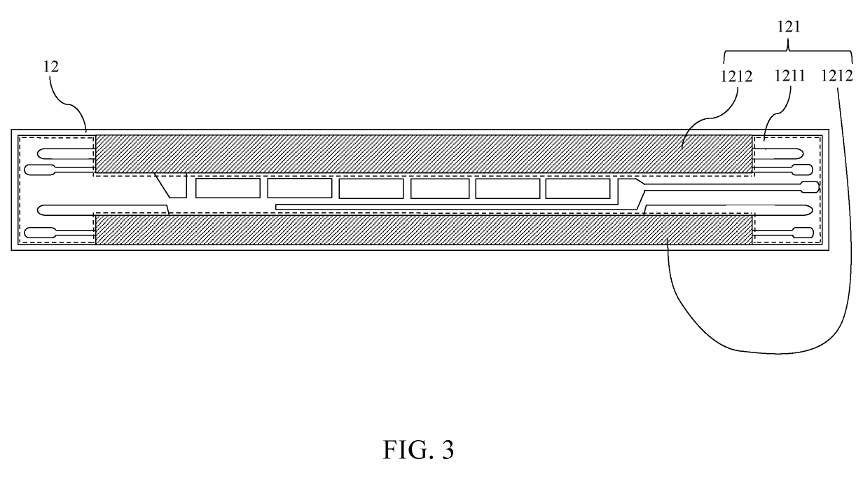

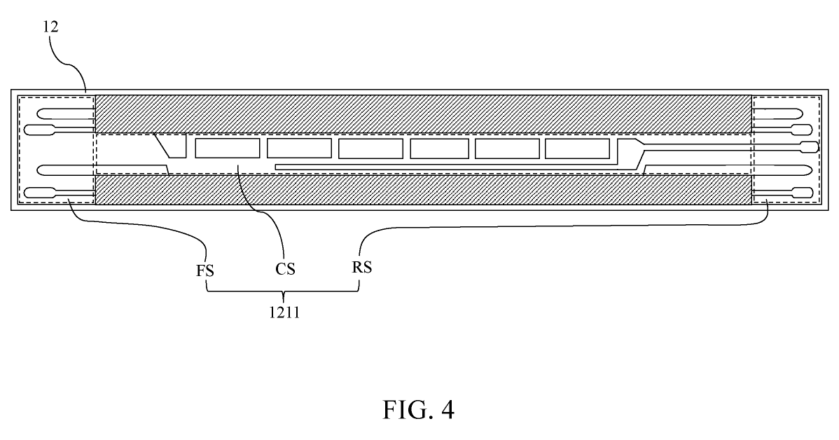

Please refer to FIG. 3 and FIG. 4. FIG. 3 is a first schematic view of a circuit board of the LED lighting device in accordance with the first embodiment of the disclosure. FIG. 4 is a second schematic view of the circuit board of the LED lighting device in accordance with the first embodiment of the disclosure. As shown in FIG. 3, the circuit board 12 has a protective layer 121. The protective layer 121 includes an opening 1211 and two coated layers 1212. The coated layers 1212 may be ink layers capable of providing the insulating function and protecting the circuit board 12. The material of the coated layers 1212 is known by those skilled in the art, so will not be described herein.

As shown in FIG. 4, the opening 1211 includes a front section FS, a rear section RS and a connecting section CS. In this embodiment, the shape of the connecting section CS is a straight line. The front section FS is connected to the rear section RS via the connecting section CS, such that the opening 1211 can be H-shaped. The coated layers 1212 are disposed on the two sides of the connecting section CS respectively.

The embodiment just exemplifies the disclosure and is not intended to limit the scope of the disclosure; any equivalent modification and variation according to the spirit of the disclosure is to be also included within the scope of the following claims and their equivalents.

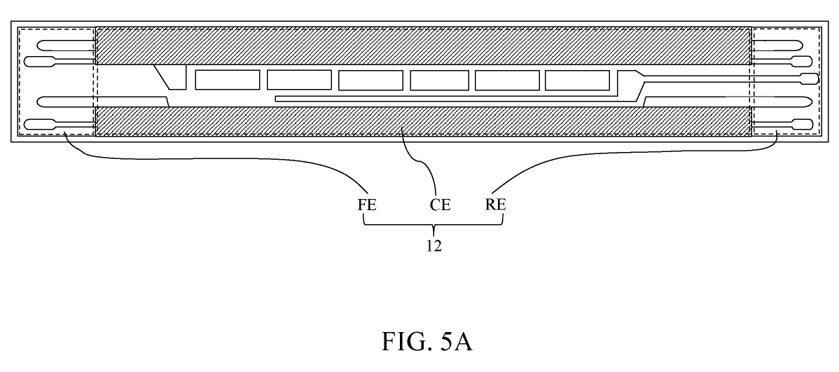

Please refer to FIG. 5A, which is a third schematic view of the circuit board of the LED lighting device in accordance with the first embodiment of the disclosure. As shown in FIG. 5A, the circuit board 12 has a front soldering section FE, a rear soldering section RE and a circuit section CE. The front soldering section FE is electrically connected to the rear soldering section RE via the circuit section CE. The light sources LD are disposed on the circuit section CE and electrically connected to the circuit section CE. Any one of the coated layers 1212 of the protective layer 121 is separated from the front soldering section FE by a predetermined distance (in one embodiment, the predetermined distance may be greater than 4m). Similarly, any one of the coated layers 1212 of the protective layer 121 is separated from the rear soldering section RE by the predetermined distance. The aforementioned predetermined distance can avoid that the halogen elements of the protective layer 121 move to the front soldering section FE and the rear soldering section RE of the circuit board 12.

The front soldering section FE has several connecting points, which may include a positive electrode, a negative electrode, a grounding point, etc. The rear soldering section RE also has the same structure. The circuit section CE has a plurality of traces. The light sources LD are disposed on the circuit board 12 and within the connecting section CS so as to electrically connect to the traces, such that the light sources LD can be electrically connected to the front soldering section FE and the rear soldering section RE via these traces.

As previously stated, the protective layer 121 of the circuit board 12 of the lighting device 1 has only one opening 1211. Therefore, the coating process of the protective layer 121 can be significantly simplified, such that the manufacturing cost of the LED lighting device 1 can be greatly reduced.

Besides, the above structural design can avoid that the halogen elements of the protective layer 121 move to the front soldering section FE and the rear soldering section RE of the circuit board 12. As a result, the front soldering section FE and the rear soldering section RE of the circuit board 12 will not be oxidized, which can make sure that the front soldering section FE and the rear soldering section RE of the circuit board 12 can achieve great conductivity and soldering effect during the manufacturing process.

In addition, the circuit board 12 of the LED lighting device 1 may further include a multi-function layer (not shown in the drawings). The multi-function layer can cover the opening 1211 of the protective layer 121 and the light sources LD disposed on the circuit board 12. The multi-function layer may be a transparent ink layer and can provide one or more of antioxidant function, insulating function, light reflecting function, moisture-proof function, etc. The material of the multi-function layer is known by those skilled in the art, so will not be described herein. Therefore, the LED lighting device 1 can have high reliability with a view to improving the overall quality thereof.

The embodiment just exemplifies the disclosure and is not intended to limit the scope of the disclosure; any equivalent modification and variation according to the spirit of the disclosure is to be also included within the scope of the following claims and their equivalents.

Please refer to FIG. 5B, which is a fourth schematic view of the circuit board of the LED lighting device in accordance with the first embodiment of the disclosure. As shown in FIG. 5B, the circuit board 12 is disposed in the light cover 11. The light sources LD are disposed in the circuit section CE, so a light-emitting zone LZ is formed (the light-emitting zone LZ is shown in FIG. 5B by one-point chain line; the light-emitting zone LZ stands for the zone which can emit light).

The light-emitting zone LZ can emit light, and the light can spread over the inner space of the light cover 11 to make the inner space of the light cover 11 form an optical zone XZ (the optical zone XZ is shown in FIG. 5B by two-point chain line; the optical zone XZ stands for the zone inside the light cover 11 filled with light). The optical zone XZ simultaneously covers the light-emitting zone LZ, the front soldering section FE and the rear soldering section RE.

Via the above optical structure design, the optical zone XZ of the light cover 11 can be further extended to cover the front soldering section FE and the rear soldering section RE of the circuit board 12 (the power supplier 14 is still outside the optical zone XZ), which can further expand the optical zone XZ of the light cover 11. Thus, the overall light-emitting area of the LED lighting device 1 can be significantly increased, so the light efficiency of the LED lighting device 1 can be enhanced.

The embodiment just exemplifies the disclosure and is not intended to limit the scope of the disclosure; any equivalent modification and variation according to the spirit of the disclosure is to be also included within the scope of the following claims and their equivalents.

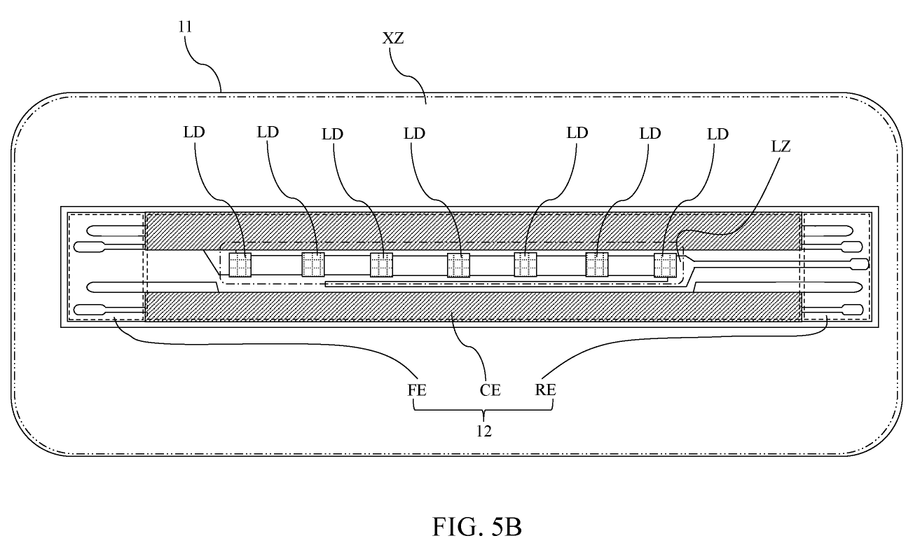

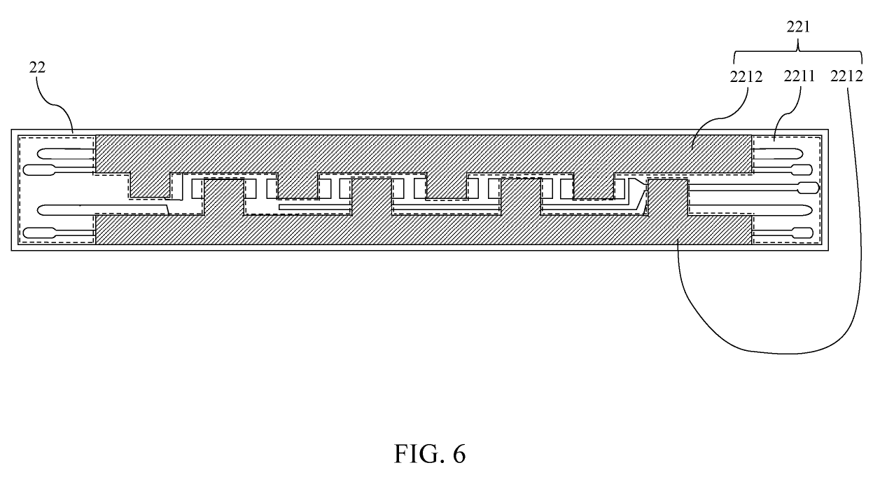

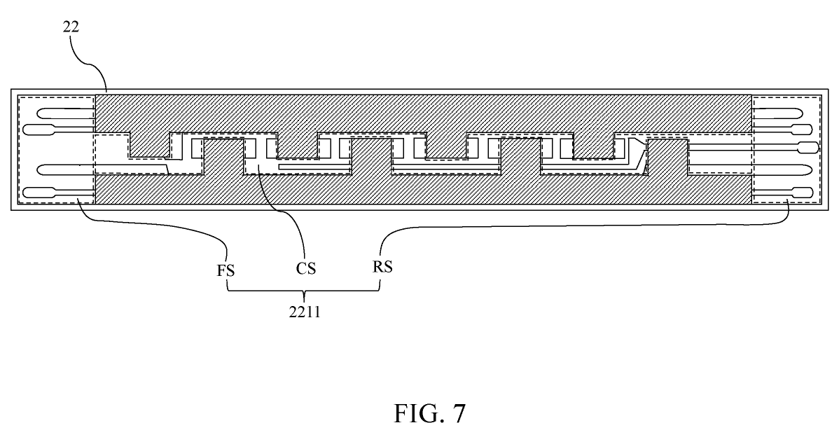

Please refer to FIG. 6, FIG. 7 and FIG. 8. FIG. 6 is a first schematic view of a circuit board of the LED lighting device in accordance with a second embodiment of the disclosure. FIG. 7 is a second schematic view of the circuit board of the LED lighting device in accordance with the second embodiment of the disclosure. FIG. 8 is a third schematic view of the circuit board of the LED lighting device in accordance with the second embodiment of the disclosure. As shown in FIG. 6, the circuit board 22 has a protective layer 221. The protective layer 221 includes an opening 2211 and two coated layers 2212. Similarly, the coated layers 2212 may be ink layers capable of providing the insulating function and protecting the circuit board 22.

As shown in FIG. 7, the opening 2211 includes a front section FS, a rear section RS and a connecting section CS. The front section FS is connected to the rear section RS via the connecting section CS. The coated layers 2212 are disposed on the two sides of the connecting section CS respectively.

As shown in FIG. 8, the difference between this embodiment and the previous embodiment is that the connecting section CS of the opening 2211 includes a plurality of bending portions C1 and a plurality of connecting portions C2 connected to each other and arranged in an alternating order. Any one of the bending portions C1 is connected to the bending portion C1 adjacent thereto via one of the connecting portions C2.

In this embodiment, each of the bending portions C1 includes two vertical portions VP and a horizontal portion HP connected to each other and perpendicular to each other, such that the shape of the bending portion C1 is U-shaped. In another embodiment, the shape of the bending portion C1 may be inverted U-shaped. In still another embodiment, each of the bending portions C1 may have only one vertical portion VP and one horizontal portion HP connected to each other and perpendicular to each other. The structure of the bending portion C1 can be changed according to actual requirements.

Besides, the width of the horizontal portion HP is greater than the width of the connecting portion C2. In another embodiment, the width of the horizontal portion HP may be equal to or less than the width of the connecting portion C2. Therefore, in this embodiment, the shape of the connecting section CS is a rectangular wave. In another embodiment, the shape of the connecting section CS may be a sinusoidal wave. Of course, the shape of the connecting section CS can be changed according to actual requirements.

The embodiment just exemplifies the disclosure and is not intended to limit the scope of the disclosure; any equivalent modification and variation according to the spirit of the disclosure is to be also included within the scope of the following claims and their equivalents.

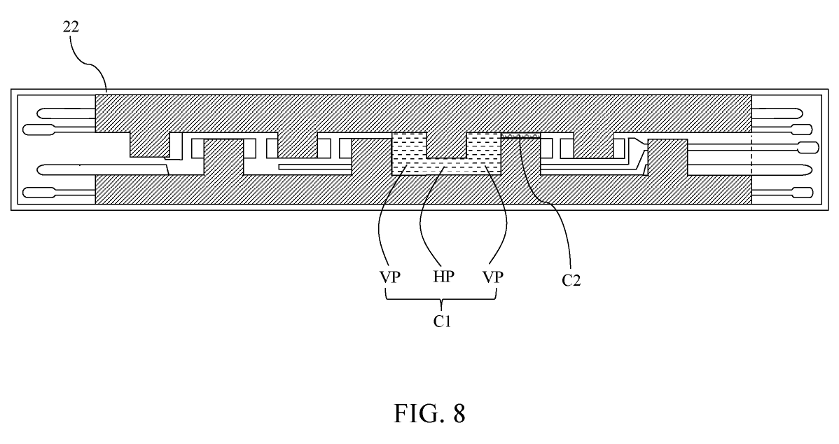

Please refer to FIG. 9, which is a fourth schematic view of the circuit board of the LED lighting device in accordance with the second embodiment of the disclosure. As shown in FIG. 9, the circuit board 22 has a front soldering section FE, a rear soldering section RE and a circuit section CE. The front soldering section FE is electrically connected to the rear soldering section RE via the circuit section CE. The light sources LD are disposed on the circuit section CE (and within the connecting section CS) and electrically connected to the circuit section CE. Any one of the coated layers 2212 of the protective layer 221 is separated from the front soldering section FE by a predetermined distance (as set forth above, the predetermined distance may be greater than 4m). Similarly, any one of the coated layers 2212 of the protective layer 221 is separated from the rear soldering section RE by the predetermined distance. The structure of the circuit board 22 is the same with that of the circuit board 22 of the previous embodiment, so will not be described herein again.

As previously stated, the protective layer 221 of the circuit board 22 has only one opening 2211. Therefore, the coating process of the protective layer 221 can be significantly simplified, such that the manufacturing cost of the LED lighting device can be greatly reduced.

Moreover, since the shape of the opening 2211 of the protective layer 221 is a rectangular wave (serrated), each of the coated layers 2212 has several protrusions, so the area of the protective layer 221 can increase. Accordingly, the protective layer 221 can cover more of the area of the surface of the circuit board 22 so as to more effectively protect the circuit board 22.

Similarly, the above structural design can avoid that the halogen elements of the protective layer 221 move to the front soldering section FE and the rear soldering section RE of the circuit board 22. As a result, the front soldering section FE and the rear soldering section RE of the circuit board 22 will not be oxidized, which can make sure that the front soldering section FE and the rear soldering section RE of the circuit board 22 can achieve great conductivity and soldering effect during the manufacturing process. The circuit board 22 may also include a multi-function layer (not shown in the drawings).

The embodiment just exemplifies the disclosure and is not intended to limit the scope of the disclosure; any equivalent modification and variation according to the spirit of the disclosure is to be also included within the scope of the following claims and their equivalents.

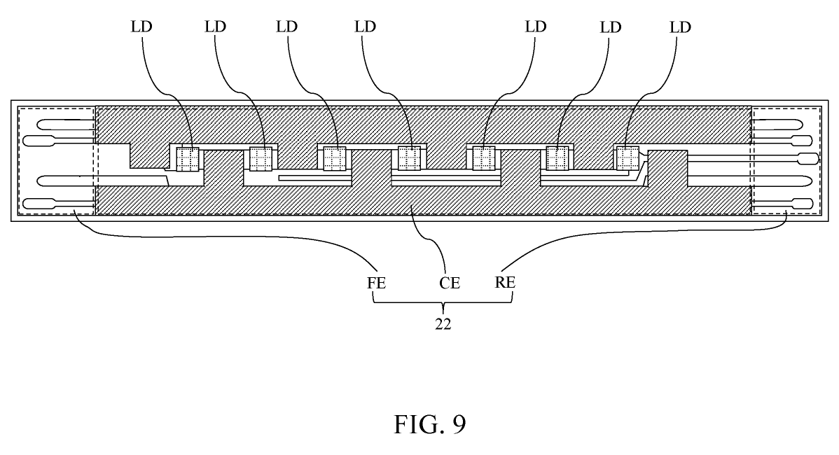

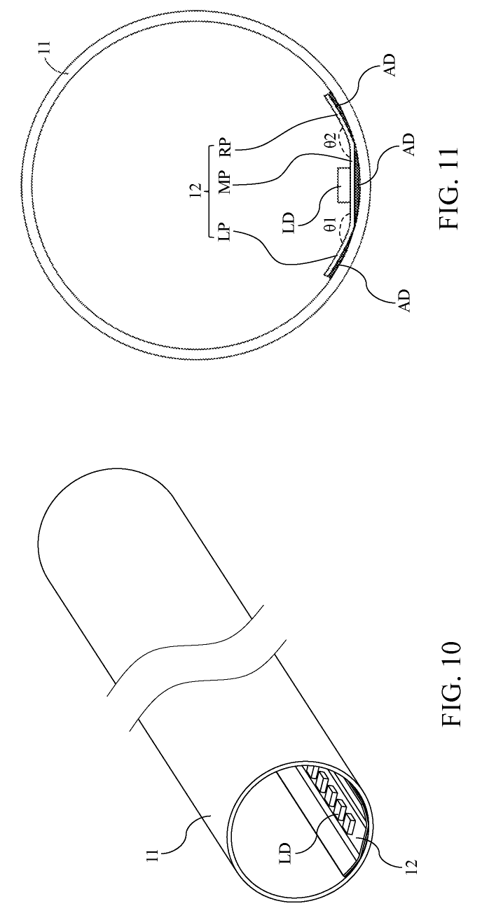

Please refer to FIG. 10 and FIG. 11. FIG. 10 is an enlargement view of a light cover of an LED lighting device in accordance with a third embodiment of the disclosure. FIG. 11 is a sectional view of the LED lighting device in accordance with the third embodiment of the disclosure. As shown in FIG. 10 and FIG. 11, the difference between this embodiment and the previous embodiments is that the circuit board 12 of this embodiment is bent. The circuit board 12 may be a flexible printed circuit board (FPCB).

The circuit board 12 includes a left-wing portion LP, a right-wing portion RP, and a flat portion MP. The left-wing portion LP, right-wing portion RP, and flat portion MP are flat (planar in shape). The left-wing portion LP and the right-wing portion RP respectively extend from both sides of the flat portion MP, such that the flat portion MP is located between the left-wing portion LP and right-wing portion RP. The left-wing portion LP and the right-wing portion RP are not parallel to the flat portion MP. Thus, the circuit board 12 may be bent. In another embodiment, the left-wing portion LP and the right-wing portion RP may also be bent.

An included angle θ1 is formed between the left-wing portion LP and the flat portion MP, and the included angle θ1 is greater than 90°. An included angle θ2 is formed between the right-wing portion RP and the flat portion MP, and the included angle θ2 is also greater than 90°. For example, the included angles θ1 and θ2 may be 150°. In other examples, the included angles θ1 and θ2 may be 160°, or even 165°. The included angles θ1 and θ2 may vary according to actual requirements, so that the circuit board 12 can conform as closely as possible to the inner surface of the light cover 11. The circuit board 12 may be adhered to the inner surface of the light cover 11 via an adhesive material AD. During the process of adhering the circuit board 12 to the inner surface of the light cover 11 with the adhesive material AD, the adhesive material AD is flattened and forms a uniform protective layer. In one embodiment, the adhesive material AD may be silicone adhesive, epoxy resin, thermally conductive silicone, or other currently available adhesive compounds.

If the circuit board 12 is planar, it would experience significant stress when fixed to the inner surface of the light cover 11, possibly leading to damage due to stress. In contrast, in this embodiment, since the circuit board 12 is bent, the stress exerted on the circuit board 12 can be greatly reduced. In addition, the protective layer formed by the adhesive material AD can further disperse stress, thereby further reducing the stress applied to the circuit board 12. As such, the service life of the LED lighting device 1 can be significantly extended, meeting actual requirements.

The embodiment just exemplifies the disclosure and is not intended to limit the scope of the disclosure; any equivalent modification and variation according to the spirit of the disclosure is to be also included within the scope of the following claims and their equivalents.

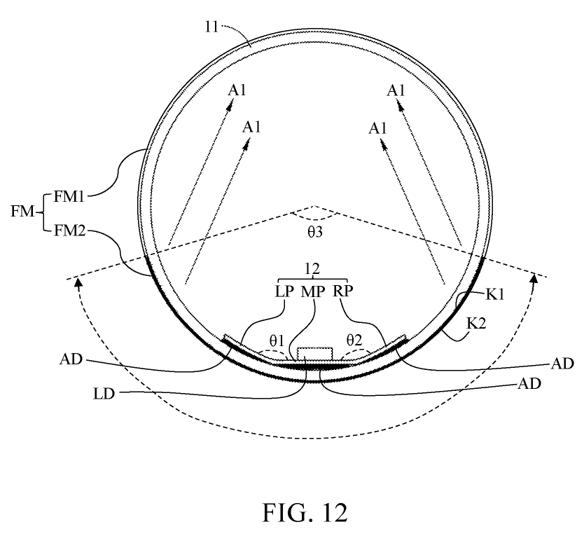

Please refer to FIG. 12, which is a sectional view of an LED lighting device in accordance with a fourth embodiment of the disclosure. As shown in FIG. 12, the difference between this embodiment and the previous embodiments is that the surface of the light cover 11 is enclosed by an optical film FM. The optical film FM includes a transparent portion FM1 and a non-transparent portion FM2. In one embodiment, the optical film FM may be made from polymer materials of at least two different colors, such as PET, OPP, or other similar materials.

The distance between the non-transparent portion FM2 and the circuit board 12 is less than the distance between the transparent portion FM1 and the circuit board 12. As can be seen in the figure, the non-transparent portion FM2 is located closer to the circuit board 12; therefore, the transparent portion FM1 faces the light source LD. The area of the non-transparent portion FM2 is greater than or at least equal to the area of the circuit board 12, allowing the non-transparent portion FM2 to conceal the adhesive material AD. The central angle θ3 corresponding to the arc formed by the cross-section of the optical film FM may range from 30° to 180°. For example, the central angle may be 35°, 60°, 100°, 130°, or 170°. The central angle may vary depending on actual requirements to meet different application needs.

In addition, the inner surface of the non-transparent portion FM2 serves as a reflective surface K1, while the outer surface of the non-transparent portion FM2 functions as a light-shielding surface K2. The light-blocking surface K2 can effectively block light. Most of the light emitted by the light source LD passes directly through the transparent portion FM1, while a portion of the light is reflected by the reflective surface K1 and also passes through the transparent portion FM1. In this way, the light efficacy of the LED lighting device 1 can be further improved, thereby enhancing the overall performance of the LED lighting device 1.

With the dual-color optical film design described above, traces of the adhesive material AD can be shielded by the non-transparent portion FM2 of the optical film FM, thereby improving the appearance of the LED lighting device 1 and effectively enhancing the user experience. In addition, light emitted from the light sources LD can still pass through the transparent portion FM1 of the optical film FM to provide lighting function.

On the other hand, the outer surface of the optical film FM can also include various patterns or text, which can further enhance the appearance of the LED lighting device 1 and increase the perceived quality thereof, thereby meeting the preferences of different users.

Further, since the optical film FM includes the transparent portion FM1 and non-transparent portion FM2, the user can easily identify the non-transparent portion FM2 during installation of the LED lighting device 1, allowing the user to quickly locate the transparent portion FM1 (which serves as the light-emitting surface). Therefore, with the dual-color optical film design, the user can install the LED lighting device 1 more conveniently.

The embodiment just exemplifies the disclosure and is not intended to limit the scope of the disclosure; any equivalent modification and variation according to the spirit of the disclosure is to be also included within the scope of the following claims and their equivalents.

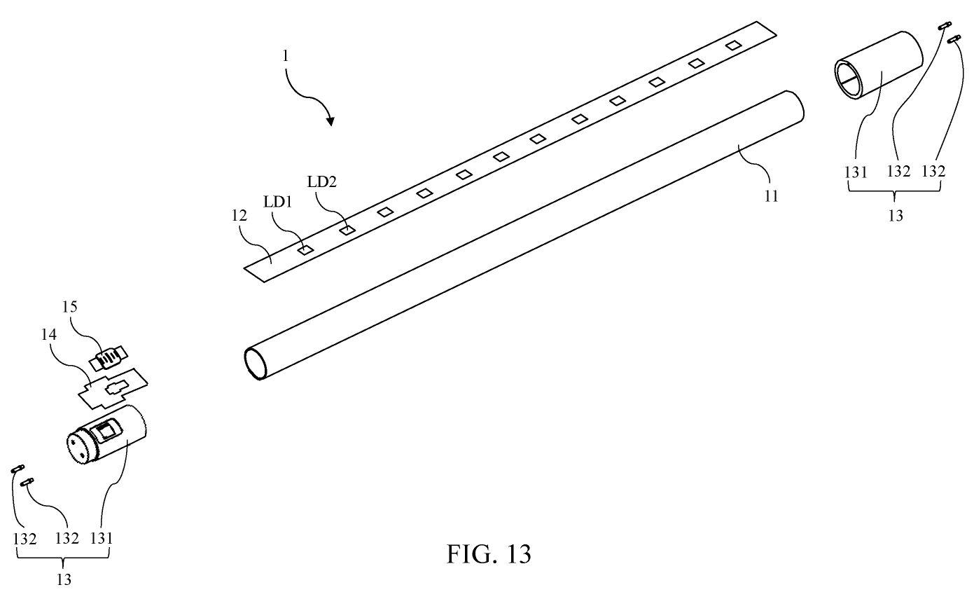

Please refer to FIG. 13, which is an exploded view of an LED lighting device in accordance with a fifth embodiment of the disclosure. As shown in FIG. 13, the LED lighting device 1 includes a light cover 11, a circuit board 12, two end caps 13, a power supplier 14, a color temperature switch 15 and a plurality of light sources LD. In this embodiment, the LED lighting device 1 is an LED light tube. In another embodiment, the LED lighting device 1 may be an LED panel light, LED ceiling light or other currently available lighting devices.

The circuit board 12 is disposed in the light cover 11. In this embodiment, the circuit board 12 is a flexible printed circuit board (FPCB). In another embodiment, the circuit board 12 is a printed circuit board. In this embodiment, the light cover 11 may be tubular. In another embodiment, the light cover 11 may be a flat circular box, a flat rectangular box, etc. In one embodiment, the light cover 11 may be made of a transparent material or a translucent material, such as plastics, glass, etc.

The two end caps 13 are disposed at the two ends of the light cover 11 and the power supplier 14 is disposed in one of the end caps 13 and electrically connected to the circuit board 12. Each of the end caps 13 includes a casing 131 and two metal pins 132 (e.g., copper, iron, aluminum, etc.). The metal pins 132 are disposed on the casing 131 and electrically connected to the power supplier 14 and the circuit board 12. In one embodiment, the power supplier 14 is an LED power supplier, which may include converters, rectifiers, filters and other necessary electronic components; the details of the power supplier 14 are known by those skilled in the art, so will not be described herein.

The light sources are disposed on the circuit board 12 and electrically connected to the circuit board 12. The light sources are LEDs. The light sources include a plurality of first light sources LD1 and a plurality of second light sources LD2. The first light sources LD1 and the second light sources LD2 are alternately arranged.

The color temperature switch 15 is disposed on one of the end caps 13 and connected to the power supplier 14. The user can operate the color temperature switch 15 to adjust the color temperature of the light sources LD. In another embodiment, the color temperature switch 15 may be replaced by a dimming switch, or the LED lighting device 1 may have both of the color temperature switch 15 and the dimming switch.

The embodiment just exemplifies the disclosure and is not intended to limit the scope of the disclosure; any equivalent modification and variation according to the spirit of the disclosure is to be also included within the scope of the following claims and their equivalents.

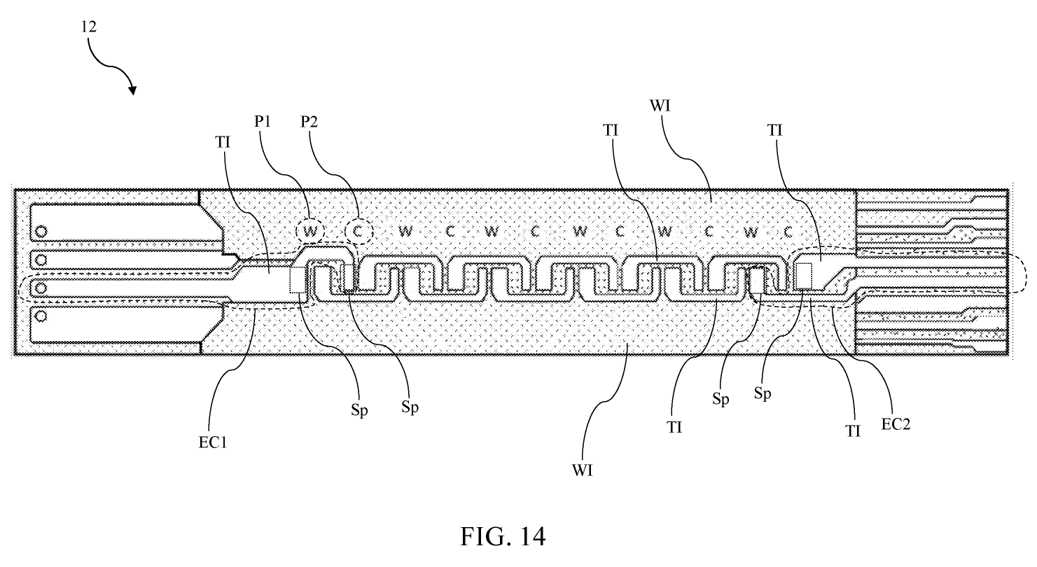

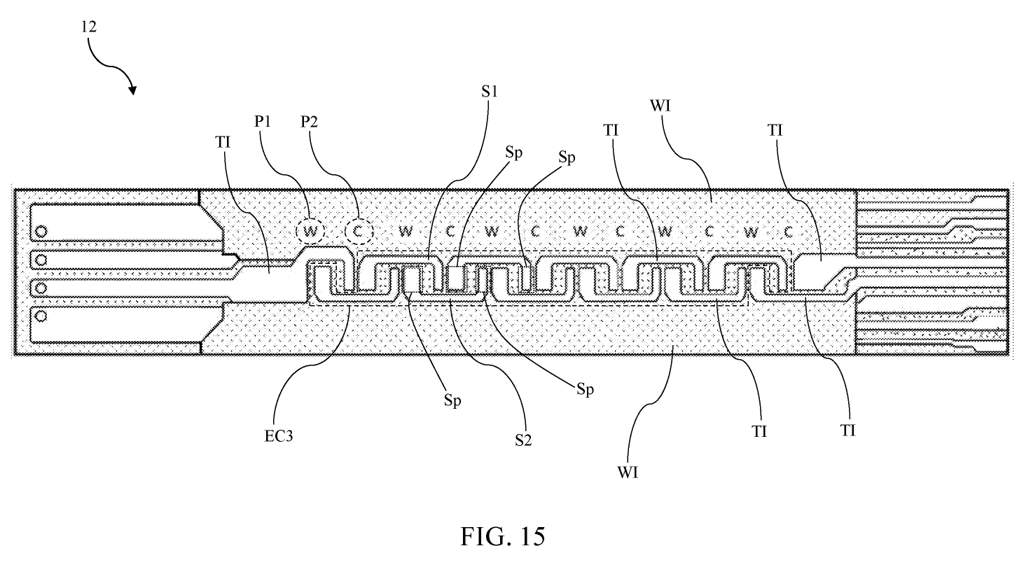

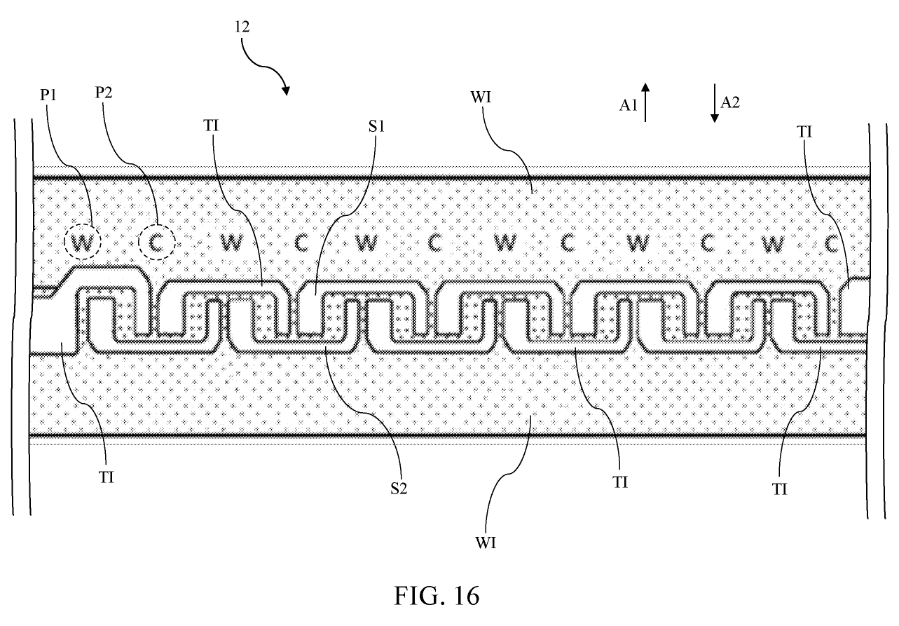

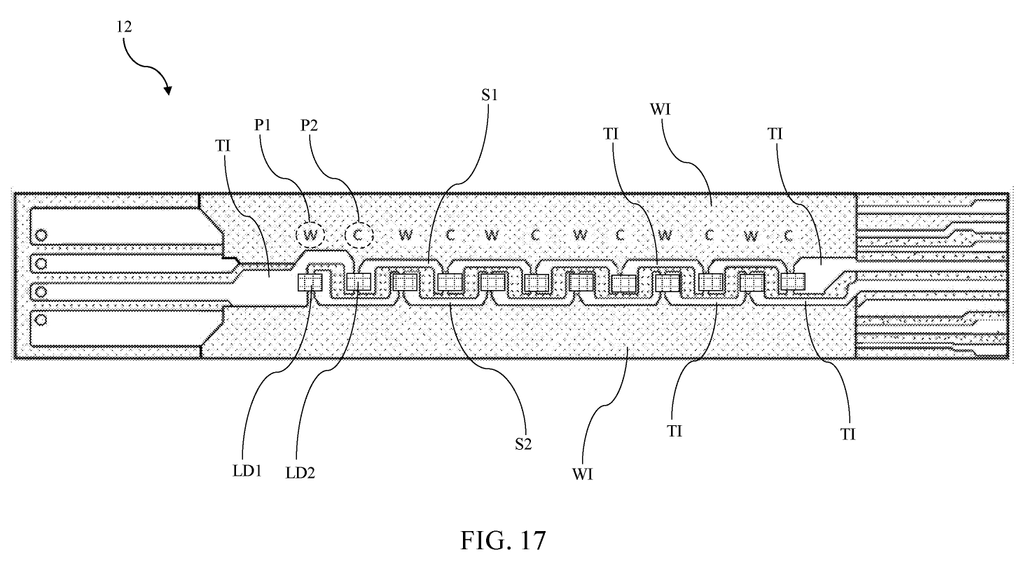

Please refer to FIG. 14, FIG. 15, FIG. 16 and FIG. 17. Please also refer to FIG. 13. FIG. 14 is a first schematic view of a circuit board of the LED lighting device in accordance with the fifth embodiment of the disclosure (without the light sources). FIG. 15 is a second schematic view of the circuit board of the LED lighting device in accordance with the fifth embodiment of the disclosure (without the light sources). FIG. 16 is a partial enlargement view of the circuit board of the LED lighting device in accordance with the fifth embodiment of the disclosure (without the light sources). FIG. 17 is a third schematic view of the circuit board of the LED lighting device in accordance with the fifth embodiment of the disclosure (with the light sources). As shown in FIG. 14, FIG. 15, FIG. 16 and FIG. 17, the circuit board 12 includes a first electrical connection region EC1, a second electrical connection region EC2, and a circuit connection region EC3. The first electrical connection region EC1, the two second electrical connection regions EC2, and the circuit connection region EC3 are formed of conductive copper foil.

The first electrical connection region EC1 is connected to the positive output terminal of the power supplier 14, and the second electrical connection region EC2 is connected to the negative output terminal of the power supplier 14.

The circuit connection region EC3 includes a plurality of first curved portions S1 and a plurality of second curved portions S2. Each first curved portion S1 protrudes in the first direction A1, and each second curved portion S2 protrudes in the second direction A2 opposite to the first direction A1. The first curved portions S1 and the second curved portions S2 are alternately arranged so that each first curved portion S1 defines an interlocking contour with two adjacent second curved portions S2 (each second curved portion S2 likewise defines an interlocking contour with two adjacent first curved portions S1). Accordingly, the circuit connection region EC3 exhibits an overall chain-link structure in which the curved portions are interlocked with one another.

The above chain-link structure provides a certain amount of expansion and contraction buffering space for absorbing displacement caused by thermal expansion and contraction, thereby effectively reducing the likelihood of warping, cracking, or delamination of the circuit connection region EC3.

In addition, the chain-link structure provides a certain degree of expansion and contraction buffering space, which can effectively reduce fatigue damage accumulated during prolonged thermal cycling. As a result, the conductive copper foil and solder joints are capable of maintaining improved mechanical strength and electrical connection reliability so as to decrease the frequency of repair and replacement of the circuit board 12, and enhance the long-term reliability and durability of the circuit board 12.

In addition, the chain-link structure forms a regular and distinctive geometric appearance, which can enhance the recognizability and design aesthetics of the circuit board 12. Accordingly, the circuit board 12 has a more attractive appearance and enhanced visual characteristics in order to further increase the overall added value of the circuit board 12.

The light sources are respectively disposed on the first electrical connection region EC1, the second electrical connection region EC2, and the circuit connection region EC3 so as to electrically connect the first electrical connection region EC1, the second electrical connection region EC2, and the circuit connection region EC3 with each other. The first electrical connection region EC1 includes two pads Sp. Each second electrical connection region EC2 includes two pads Sp. Each first curved portion S1 includes two pads Sp disposed on opposite sides thereof. Likewise, each second curved portion S2 includes two pads Sp disposed on opposite sides thereof. Each light source is soldered to two adjacent pads Sp. Accordingly, the power supplier 14, the first electrical connection region EC1, the second electrical connection region EC2, the circuit connection region EC3, and the light sources together form a complete electrical circuit.

The light sources include a plurality of first light sources LD1 and a plurality of second light sources LD2. The first light sources LD1 and the second light sources LD2 are alternately arranged. The first light sources LD1 have a higher color temperature than the second light sources LD2.

The circuit board 12 further includes a plurality of first silkscreen markings P1 and a plurality of second silkscreen markings P2. The first silkscreen markings P1 and the second silkscreen markings P2 are also alternately arranged. The first silkscreen markings P1 are respectively corresponding to the first light sources LD1, and indicate the installation positions thereof, while the second silkscreen markings P2 are respectively corresponding to the second light sources LD2, and indicate the installation positions thereof. Accordingly, manufacturing personnel can readily identify the installation positions of the first light sources LD1 and the second light sources LD2 in order to correctly solder the first light sources LD1 and the second light sources LD2 onto the circuit board 12.

By virtue of the above arrangement of the light sources, light emitted from the first light sources LD1 and the second light sources LD2 can be uniformly mixed, which can provide more uniform illumination from the LED lighting device 1. In addition, adjustment of the color temperature of the LED lighting device 1 becomes smoother and more natural so as to improve the overall lighting performance of the LED lighting device 1. Furthermore, the above arrangement of the light sources also reduces the influence of the first silkscreen markings P1 and the second silkscreen markings P2 on the emitted light.

In addition, the regions of the first electrical connection region EC1, the second electrical connection region EC2, and the circuit connection region EC3 (formed of conductive copper foil) that are not in contact with the light sources are covered with transparent ink TI (namely the regions other than the pads Sp). The regions of the circuit board 12 other than the first electrical connection region EC1, the second electrical connection region EC2, and the circuit connection region EC3 are covered with white ink WI (The transparent ink TI covers the entire surface of the conductive copper foil except for the pads Sp, while the white ink WI covers regions of the circuit board 12 that are not covered by the transparent ink TI). Since the transparent ink TI does not conceal the metallic appearance of the first electrical connection region EC1, the second electrical connection region EC2, and the circuit connection region EC3 (formed of conductive copper foil), the chain-link structure can be fully exhibited and forms a distinct high-contrast visual effect with the regions covered by the white ink WI. Accordingly, the user can more readily recognize the chain-link structure, which can further enhance the appearance and visual distinctiveness of the circuit board 12. Meanwhile, the transparent ink TI also provides excellent electrical insulation, moisture resistance, contamination resistance, and arc-resistant protection, which can achieve both improved appearance and enhanced electrical safety.

Furthermore, a plurality of interconnected gaps are formed between adjacent portions of the chain-link structure, allowing the white ink WI covering the upper portion of the circuit board 12 and the white ink WI covering the lower portion of the circuit board 12 to be connected to each other through the gaps, which can form a complete and continuous protective layer. Since the white ink WI forms a relatively large-area and continuous protective layer, the white ink WI is less likely to peel, crack, or suffer from local stress concentration due to local discontinuities, which can make the protective layer more complete and improve long-term weather resistance. Accordingly, the likelihood that moisture, dust, contaminants, or corrosive media penetrate the surface of the circuit board 12 through gaps in the protective layer can be effectively reduced with a view to further improving the moisture resistance, oxidation resistance, insulating performance, environmental resistance, and durability of the circuit board 12. Therefore, the circuit board 12 can maintain stable and reliable electrical performance during long-term use, which can significantly improve the reliability and service life of the LED lighting device 1.

The embodiment just exemplifies the disclosure and is not intended to limit the scope of the disclosure; any equivalent modification and variation according to the spirit of the disclosure is to be also included within the scope of the following claims and their equivalents.

To sum up, according to one embodiment of the disclosure, an LED lighting device includes a power supplier, a light cover, a circuit board and a plurality of light sources. The circuit board is disposed in the light cover. The circuit board includes a first electrical connection region, a second electrical connection region, and a circuit connection region. The first electrical connection region is connected to the positive output terminal of the power supplier, and the second electrical connection region is connected to the negative output terminal of the power supplier. The circuit connection region includes a plurality of first curved portions and a plurality of second curved portions. Each of the first curved portions protrudes in a first direction, each of the second curved portions protrudes in a second direction opposite to the first direction. The first curved portions and the second curved portions are alternately arranged to form a chain-link structure. The light sources are respectively disposed on the first electrical connection region, the second electrical connection region, and the circuit connection region, such that the first electrical connection region, the second electrical connection region, and the circuit connection region are electrically connected to each other. The chain-link structure provides a certain degree of expansion and contraction buffering space for absorbing displacement caused by thermal expansion and contraction, which can effectively reduce the likelihood of warpage, cracking, or delamination of the circuit connection region.

Also, according to one embodiment of the disclosure, the circuit connection region of the circuit board of the LED lighting device forms the chain-link structure. The chain-link structure provides a regular and distinctive geometric appearance, which can enhance the recognizability and design aesthetics of the circuit board. Accordingly, the circuit board has a more attractive appearance and enhanced visual characteristics, which can further increase the overall added value of the circuit board.

Further, according to one embodiment of the disclosure, the regions of the first electrical connection region, the second electrical connection region, and the circuit connection region of the circuit board that are not in contact with the light sources are covered with transparent ink. The regions of the circuit board other than the first electrical connection region, the second electrical connection region, and the circuit connection region are covered with white ink. Since the transparent ink does not conceal the metallic appearance of the first electrical connection region, the second electrical connection region, and the circuit connection region (formed of conductive copper foil), the chain-link structure can be fully exhibited and forms a distinct high-contrast visual effect with the regions covered by the white ink. Accordingly, the user can more readily recognize the chain-link structure, which can further enhance the appearance and visual distinctiveness of the circuit board. Meanwhile, the transparent ink also provides excellent electrical insulation, moisture resistance, contamination resistance, and arc-resistant protection, which can achieve both improved appearance and enhanced electrical safety.

Moreover, according to one embodiment of the disclosure, a plurality of interconnected gaps are formed between adjacent portions of the chain-link structure, allowing the white ink covering the upper portion of the circuit board and the white ink covering the lower portion of the circuit board to communicate with each other through the gaps so as to form a continuous and integral protective layer. Accordingly, interruption of the white ink by the conductive copper foil can be avoided, which can effectively reduce the likelihood that moisture, dust, contaminants, or corrosive media penetrate the surface of the circuit board through gaps in the protective layer. As a result, the moisture resistance, oxidation resistance, electrical insulation, environmental resistance, and durability of the circuit board are further improved. Therefore, the circuit board is capable of maintaining stable and reliable electrical performance over an extended period of use, so the reliability and service life of the LED lighting device can be significantly improved.

Furthermore, according to one embodiment of the disclosure, the light sources include a plurality of first light sources and a plurality of second light sources, and the first light sources and the second light sources are alternately arranged. The first light sources have a higher color temperature than the second light sources. By virtue of the above arrangement of the light sources, light emitted from the first light sources and the second light sources can be uniformly mixed in order to provide more uniform illumination from the LED lighting device. In addition, adjustment of the color temperature of the LED lighting device becomes smoother and more natural, which can improve the overall lighting performance of the LED lighting device.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A light-emitting diode (LED) lighting device, comprising:
a power supplier;
a light cover; and
a circuit board disposed in the light cover, and comprising a first electrical connection region, a second electrical connection region, and a circuit connection region, wherein the first electrical connection region is connected to a positive output terminal of the power supplier, the second electrical connection region is connected to a negative output terminal of the power supplier, and the circuit connection region comprises a plurality of first curved portions and a plurality of second curved portions, wherein each of the first curved portions protrudes in a first direction, each of the second curved portions protrudes in a second direction opposite to the first direction, and the first curved portions and the second curved portions are alternately arranged to form a chain-link structure; and
a plurality of light sources respectively disposed on the first electrical connection region, the second electrical connection region, and the circuit connection region, whereby the first electrical connection region, the second electrical connection region, and the circuit connection region are electrically connected to each other.

2. The LED lighting device as claimed in claim 1, wherein regions of the first electrical connection region, the second electrical connection region, and the circuit connection region that are not in contact with the light sources are covered with transparent ink.

3. The LED lighting device as claimed in claim 2, wherein regions of the circuit board other than the first electrical connection region, the second electrical connection region, and the circuit connection region are covered with white ink.

4. The LED lighting device as claimed in claim 3, wherein the light sources comprise a plurality of first light sources and a plurality of second light sources, and the first light sources and the second light sources are alternately arranged.

5. The LED lighting device as claimed in claim 4, wherein a color temperature of the first light source is higher than a color temperature of the second light source.

6. The LED lighting device as claimed in claim 4, wherein the circuit board comprises a first silkscreen marking and a second silkscreen marking, and the first silkscreen marking is corresponding to one of the first light sources, and the second silkscreen marking is corresponding to one of the second light sources.

7. The LED lighting device as claimed in claim 1, wherein the circuit board is a flexible printed circuit board.

8. The LED lighting device as claimed in claim 1, wherein the light sources are LEDs.

9. The LED lighting device as claimed in claim 1, further comprising two end caps, wherein the two end caps are disposed at two ends of the light cover and the power supplier is disposed in one of the end caps.

10. The LED lighting device as claimed in claim 1, wherein the light cover is made of a transparent material or a semi-transparent material.
